(19) United States
(12) Patent Application Publication
(10) Pub. No.: US 2014/0009236 A1
(43) Pub. Date: Jan. 9, 2014

(54) CONFIGURABLE MULTI-MODE OSCILLATORS

(71) Applicants: Jaehyouk Choi, San Diego, CA (US); Yiwu Tang, San Diego, CA (US)

(72) Inventors: Jaehyouk Choi, San Diego, CA (US); Yiwu Tang, San Diego, CA (US)

(73) Assignee: QUALCOMM INCORPORATED

(21) Appl. No.: 13/541,258

(22) Filed: Jul. 3, 2012

(51) Int. Cl. H03B 5/12

(52) U.S. Cl. 331/117 FE

(57) ABSTRACT

Multi-mode oscillators supporting multiple modes and having different desirable characteristics (e.g., good phase noise or low power consumption) in different modes are disclosed. In an exemplary design, an apparatus includes first and second transistors of a first transistor type (e.g., NMOS transistors) and third and fourth transistors of a second transistor type (e.g., PMOS transistors) for a multi-mode oscillator. The third and fourth transistors are coupled (e.g., directly) to the first and second transistors. The first and second transistors are enabled in a first mode to provide signal gain for the oscillator and generate an oscillator signal in the first mode. The first to fourth transistors are enabled in a second mode to provide signal gain for the oscillator and generate the oscillator signal in the second mode. Different supply voltages may be provided at different supply nodes of the oscillator in the first and second modes.

### BACKGROUND

I. Field

The present invention relates generally to circuits, and more specifically to oscillators.

II. Background

A wireless device (e.g., a cellular phone or a smartphone) may transmit and receive data for two-way communication with a wireless communication system. The wireless device may include a transmitter for data transmission and a receiver for data reception. For data transmission, the transmitter may modulate a transmit local oscillator (LO) signal with data to obtain a modulated radio frequency (RF) signal, amplify the modulated RF signal to obtain an output RF signal having the desired output power level, and transmit the output RF signal via an antenna to a base station. For data reception, the receiver may obtain a received RF signal via the antenna, amplify and downconvert the received RF signal with a receive LO signal, and process the downconverted signal to recover data sent by the base station.

The wireless device may include one or more oscillators to generate one or more oscillator signals at one or more desired frequencies. The oscillator signal(s) may be used to generate the transmit LO signal for the transmitter and the receive LO signal for the receiver. The oscillator(s) may be required to generate the oscillator signal(s) to meet the requirements of the wireless communication system with which the wireless device communicates. The oscillator(s) should also consume as little battery power as possible in order to extend battery life and prolong standby time and talk time of the wireless device.

### SUMMARY

Multi-mode oscillators capable of operating in one of multiple operating modes (or simply, “modes”) at any given moment are disclosed herein. A multi-mode oscillator may have different desirable characteristics in different modes, e.g., good phase noise performance in one mode, and low power consumption in another mode. A suitable mode may be selected for the multi-mode oscillator depending on the desired characteristics.

In an exemplary design, an apparatus may include first and second transistors of a first transistor type and third and fourth transistors of a second transistor type for a multi-mode oscillator. The second transistor type may be complementary to the first transistor type, e.g., P-type versus N-type. In one design, the multi-mode oscillator may be implemented in complementary metal oxide semiconductor (CMOS), the first and second transistors may comprise N-channel metal oxide semiconductor (NMOS) transistors, and the third and fourth transistors may comprise P-channel metal oxide semiconductor (PMOS) transistors. The third and fourth transistors may be coupled (e.g., directly) to the first and second transistors (e.g., to enable use of a lower power supply voltage as compared to a case in which the third and fourth transistors are coupled to the first and second transistors via switches). The first and second transistors may be enabled in a first mode to provide signal gain for the oscillator and generate an oscillator signal in the first mode. The first, second, third and fourth transistors may be enabled in a second mode to provide signal gain for the oscillator and generate the oscillator signal in the second mode. The third and fourth transistors may be disabled in the first mode.

The apparatus may further include a cross-coupled RC circuit coupled between the third and fourth transistors. The cross-coupled RC circuit may function as a switch to disable the third and fourth transistors in the first mode. The cross-coupled RC circuit may also enable a suitable bias voltage to be applied to the third and fourth transistors in the second mode to provide more headroom and enable a lower power supply voltage to be used in the second mode (as compared to a case in which the cross-coupled RC circuit is not used).

The apparatus may further include a tank circuit including an inductor and an adjustable capacitor coupled in parallel. The inductor may have a centertap configured to receive a first supply voltage for the first and second transistors in the first mode.

The apparatus may further include a supply circuit to generate a suitable supply voltage for the multi-mode oscillator in each mode. The supply circuit may provide the first supply voltage at a first supply node (e.g., corresponding to the centertap of the inductor in the tank circuit) for the first and second transistors in the first mode. The supply circuit may float the first supply node in the second mode. The supply circuit may provide a second supply voltage at a second supply node for the first, second, third, and fourth transistors in the second mode. The supply circuit may couple the second supply node to circuit ground in the first mode to disable the third and fourth transistors in the first mode.

In one design, the first and second transistors may be cross-coupled and self-biased. In one design, the third and fourth transistors may receive (i) a first bias voltage to disable the third and four transistors in the first mode or (ii) a second bias voltage to enable the third and four transistors in the second mode. The first bias voltage may be set to a supply voltage, and the second bias voltage may be set to one half of the supply voltage or less.

The first and second modes may be selected for different radio technologies, which may have different oscillator requirements. The first and second modes may also be selected for different modulation orders, different received signal qualities, and/or based on other criteria.

Various aspects and features of the disclosure are described in further detail below.

### BRIEF DESCRIPTION OF THE DRAWINGS

FIG. 1 shows a wireless device capable of communicating with different wireless communication systems.

FIG. 2 shows a block diagram of the wireless device in FIG. 1.

FIG. 3 shows a schematic diagram of a multi-mode oscillator supporting an NMOS mode and a CMOS mode.

FIG. 4 shows the multi-mode oscillator in the NMOS node.

FIG. 5 shows the multi-mode oscillator in the CMOS node.

FIG. 6 shows a process for operating the multi-mode oscillator in FIG. 3.

FIG. 7 shows a schematic diagram of a multi-mode oscillator supporting a PMOS mode and a CMOS mode.

FIG. 8 shows a process for generating an oscillator signal with a multi-mode oscillator.

### DETAILED DESCRIPTION

The detailed description set forth below is intended as a description of exemplary designs of the present disclosure and is not intended to represent the only designs in which the present disclosure can be practiced. The term “exemplary” is used herein to mean “serving as an example, instance, or illustration.” Any design described herein as “exemplary” is not necessarily to be construed as preferred or advantageous over other designs. The detailed description includes specific details for the purpose of providing a thorough understanding of the exemplary designs of the present disclosure. It will be apparent to those skilled in the art that the exemplary designs described herein may be practiced without these specific details. In some instances, well-known structures and devices are shown in block diagram form in order to avoid obscuring the novelty of the exemplary designs presented herein.

Multi-mode oscillators supporting multiple modes and having different desirable characteristics in different modes are disclosed herein. The multi-mode oscillators may be used for various electronic devices such as wireless communication devices.

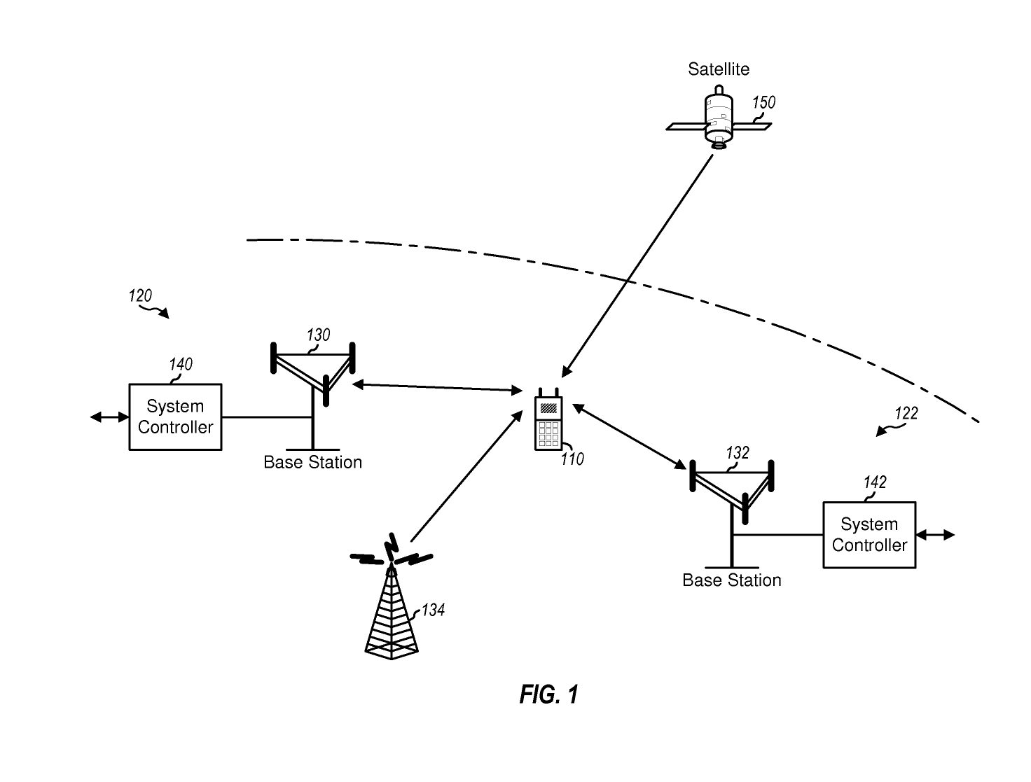

FIG. 1 shows a wireless device 110 capable of communicating with different wireless communication systems 120 and 122. Wireless systems 120 and 122 may each be a Code Division Multiple Access (CDMA) system, a Global System for Mobile Communications (GSM) system, a Long Term Evolution (LTE) system, a wireless local area network (WLAN) system, or some other wireless system. A CDMA system may implement Wideband CDMA (WCDMA), CDMA 1X or cdma2000, Time Division Synchronous Code Division Multiple Access (TD-SCDMA), or some other version of CDMA. TD-SCDMA is also referred to as Universal Terrestrial Radio Access (UTRA) Time Division Duplex (TDD) 1.28 Mcps Option or Low Chip Rate (LCR). LTE supports both frequency division duplexing (FDD) and time division duplexing (TDD). For example, wireless system 120 may be a GSM system, and wireless system 122 may be a WCDMA system. As another example, wireless system 120 may be an LTE system, and wireless system 122 may be a CDMA system.

For simplicity, FIG. 1 shows wireless system 120 including one base station 130 and one system controller 140, and wireless system 122 including one base station 132 and one system controller 142. In general, each wireless system may include any number of base stations and any set of network entities. Each base station may support communication for wireless devices within its coverage.

Wireless device 110 may also be referred to as a user equipment (UE), a mobile station, a terminal, an access terminal, a subscriber unit, a station, etc. Wireless device 110 may be a cellular phone, a smartphone, a tablet, a wireless modem, a personal digital assistant (PDA), a handheld device, a laptop computer, a smartbook, a netbook, a cordless phone, a wireless local loop (WLL) station, a Bluetooth device, etc. Wireless device 110 may be capable of communicating with wireless system 120 and/or 122. Wireless device 110 may also be capable of receiving signals from broadcast stations (e.g., a broadcast station 134). Wireless device 110 may also be capable of receiving signals from satellites (e.g., a satellite 150) in one or more global navigation satellite systems (GNSS). Wireless device 110 may support one or more radio technologies for wireless communication such as GSM, WCDMA, cdma2000, LTE, 802.11, etc. The terms “radio technology”, “radio access technology”, “air interface”, and “standard” are often used interchangeably.

Wireless device 110 may communicate with a base station in a wireless system via the downlink and uplink. The downlink (or forward link) refers to the communication link from the base station to the wireless device, and the uplink (or reverse link) refers to the communication link from the wireless device to the base station.

A wireless system may utilize TDD and/or FDD. For TDD, the downlink and uplink share the same frequency, and downlink transmissions and uplink transmissions may be sent on the same frequency in different time periods. For FDD, the downlink and uplink are allocated separate frequencies. Downlink transmissions may be sent on one frequency, and uplink transmissions may be sent on another frequency. Some exemplary radio technologies supporting TDD include GSM, LTE TDD, and TD-SCDMA. Some exemplary radio technologies supporting FDD include WCDMA, cdma2000, and LTE FDD.

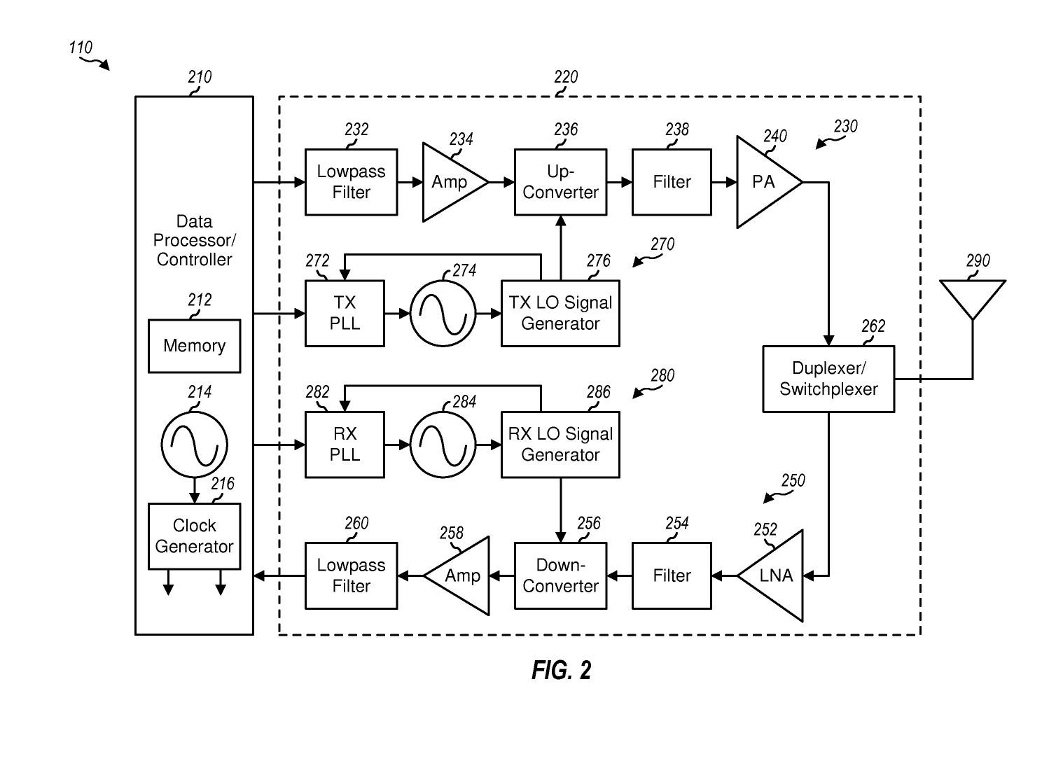

FIG. 2 shows a block diagram of an exemplary design of wireless device 110 in FIG. 1. In this exemplary design, wireless device 110 includes a data processor/controller 210, a transceiver 220, and an antenna 290. Transceiver 220 includes a transmitter 230 and a receiver 250 that support bi-directional communication.

A transmitter or a receiver may be implemented with a super-heterodyne architecture or a direct-conversion architecture. In the super-heterodyne architecture, a signal is frequency converted between RF and baseband in multiple stages, e.g., from RF to an intermediate frequency (IF) in one stage, and then from IF to baseband in another stage for a receiver. In the direct-conversion architecture, which is also referred to as a zero-IF architecture, a signal is frequency converted between RF and baseband in one stage. The super-heterodyne and direct-conversion architectures may use different circuit blocks and/or have different requirements. In the exemplary design shown in FIG. 2, transmitter 230 and receiver 250 are implemented with the direct-conversion architecture.

In the transmit path, data processor 210 may process (e.g., encode and modulate) data to be transmitted and provide an analog output signal to transmitter 230. Within transmitter 230, a lowpass filter 232 may filter the analog output signal to remove images caused by a prior digital-to-analog conversion. An amplifier (Amp) 234 may amplify the signal from lowpass filter 232 and provide an amplified baseband signal. An upconverter 236 may receive the amplified baseband signal and a transmit (TX) LO signal from an LO signal generator 276. Upconverter 236 may upconvert the amplified baseband signal with the TX LO signal and provide an upconverted signal. A filter 238 may filter the upconverted signal to remove images caused by the frequency upconversion. A power amplifier (PA) 240 may amplify the filtered RF signal from filter 238 to obtain the desired output power level and provide an output RF signal. The output RF signal may be routed through a duplexer/switchplexer 262.

For FDD, transmitter 230 and receiver 250 may be coupled to duplexer 262, which may include a TX filter for transmitter 230 and a receive (RX) filter for receiver 250. The TX filter may filter the output RF signal to pass signal components in a transmit band and attenuate signal components in a receive band. For TDD, transmitter 230 and receiver 250 may be coupled to switchplexer 262. Switchplexer 262 may pass the output RF signal from transmitter 230 to antenna 290 during uplink time intervals. For both FDD and TDD, duplexer/switchplexer 262 may provide the output RF signal to antenna 290 for transmission via a wireless channel.

In the receive path, antenna 290 may receive signals transmitted by base stations and/or other transmitter stations and may provide a received RF signal. The received RF signal may be routed through duplexer/switchplexer 262. For FDD, the RX filter within duplexer 262 may filter the received RF signal to pass signal components in a receive band and attenuate signal components in the transmit band. For TDD, switchplexer 262 may pass the received RF signal from antenna 290 to receiver 250 during downlink time intervals. For both FDD and TDD, duplexer/switchplexer 262 may provide the received RF signal to receiver 250.

Within receiver 250, the received RF signal may be amplified by a low noise amplifier (LNA) 252 and filtered by a filter 254 to obtain an input RF signal. A downconverter 256 may receive the input RF input signal and an RX LO signal from an LO signal generator 286. Downconverter 256 may downconvert the input RF signal with the RX LO signal and provide a downconverted signal. The downconverted signal may be amplified by an amplifier 258 and further filtered by a lowpass filter 260 to obtain an analog input signal, which may be provided to data processor 210.

A frequency synthesizer 270 may generate the TX LO signal for frequency upconversion and may include a phase locked loop (PLL) 272, a voltage controlled oscillator (VCO) 274, and LO signal generator 276. VCO 274 may generate a TX VCO signal at a desired frequency. LO signal generator 276 may receive the TX VCO signal and generate the TX LO signal. PLL 272 may receive timing information from data processor/controller 210 and the TX LO signal from LO signal generator 276. PLL 272 may generate a first control signal for VCO 274. The first control signal may adjust the frequency and/or phase of VCO 274 to obtain the desired frequency for the TX VCO signal.

A frequency synthesizer 280 may generate the RX LO signal for frequency downconversion and may include a PLL 282, a VCO 284, and LO signal generator 286. VCO 284 may generate an RX VCO signal at a desired frequency. LO signal generator 286 may receive the RX VCO signal and generate the RX LO signal. PLL 282 may receive timing information from data processor/controller 210 and the RX LO signal from LO signal generator 286. PLL 282 may generate a second control signal for VCO 284. The second control signal may adjust the frequency and/or phase of VCO 284 to obtain the desired frequency for the RX VCO signal.

VCOs 274 and 284 may each be implemented as described below. LO generators 276 and 286 may each include frequency dividers, buffers, etc. PLLs 272 and 282 may each include a phase/frequency detector, a loop filter, a charge pump, a frequency divider, etc. Each VCO signal and each LO signal may be a periodic signal with a particular fundamental frequency. The TX LO signal and the RX LO signal from LO generators 276 and 286 may have (i) the same frequency for TDD or (ii) different frequencies for FDD. The TX VCO signal and the RX VCO signal from VCOs 274 and 284 may have the same frequency (e.g., for TDD) or different frequencies (e.g., for FDD or TDD).

FIG. 2 shows an exemplary design of transmitter 230 and receiver 250. In general, the conditioning of the signals in a transmitter and a receiver may be performed by one or more stages of amplifier, filter, upconverter, downconverter, etc. These circuits may be arranged differently from the configuration shown in FIG. 2. Furthermore, other circuits not shown in FIG. 2 may also be used to condition the signals in the transmitter and receiver. For example, impedance matching circuits may be located at the output of PA 240, at the input of LNA 252, between antenna 290 and duplexer/switchplexer 262, etc. Some circuits in FIG. 2 may also be omitted. For example, filter 238 and/or 254 may be omitted.

All or a portion of transceiver 220 may be implemented on one or more analog integrated circuits (ICs), RF ICs (RFICs), mixed-signal ICs, etc. For example, lowpass filter 232 to PA 240 in transmitter 230, LNA 252 to lowpass filter 260 in receiver 250, PLLs 272 and 282, VCOs 274 and 284, and LO generators 276 and 286 may be implemented on an RFIC. PA 240 and possibly other circuits may also be implemented on a separate IC or circuit module.

Data processor/controller 210 may perform various functions for wireless device 110. For example, data processor 210 may perform processing for data being transmitted via transmitter 230 and received via receiver 250. Controller 210 may control the operation of various circuits within transmitter 230 and receiver 250. Memory 212 may store program codes and data for data processor/controller 210. Memory 212 may be internal to data processor/controller 210 (as shown in FIG. 2) or external to data processor/controller 210 (not shown in FIG. 2). An oscillator 214 may generate a VCO signal at a particular frequency. A clock generator 216 may receive the VCO signal from oscillator 214 and may generate clock signals for various modules within data processor/controller 210. Data processor/controller 210 may be implemented on one or more application specific integrated circuits (ASICs) and/or other ICs.

Wireless device 110 may support communication with wireless systems of different radio technologies, which may have different requirements for the TX LO signal and/or the RX LO signal. For example, wireless device 110 may support GSM and WCDMA. As another example, wireless device 110 may support LTE and CDMA. GSM and LTE may require an oscillator to have good phase noise performance. However, power consumption may be less important for GSM and/or LTE. In contrast, WCDMA may have less stringent phase noise requirements for an oscillator. However, low power consumption may be important for WCDMA. Wireless device 110 may include one or more oscillators for GSM and/or LTE and one or more oscillators for WCDMA. The oscillator(s) for GSM and/or LTE may be designed to have good phase noise performance whereas the oscillator(s) for WCDMA may be designed to consume low power. Having multiple oscillators with different characteristics (e.g., good phase noise and low power consumption) to support different radio technologies may increase circuit area, circuit complexity, and cost and may also have other disadvantages.

In an aspect of the present disclosure, a multi-mode oscillator supporting multiple modes having different characteristics may be used to support multiple radio technologies with different oscillator requirements. In one exemplary design, the multi-mode oscillator may support two modes—a high performance mode and a low power mode. In the high performance mode, the multi-mode oscillator may have good phase noise performance, may be able to operate with a lower power supply voltage (e.g., have less headroom requirements), but may have higher power consumption. In the low power mode, the multi-mode oscillator may have low power consumption but may have limited phase noise performance and may have more stringent headroom requirements. Using a single multi-mode oscillator to support multiple radio technologies with different oscillator requirements may reduce circuit area, circuit complexity, and cost and may also have other advantages.

A multi-mode oscillator may be implemented with transistors of various types. Several exemplary designs of multi-mode oscillators implemented in CMOS with NMOS transistors and PMOS transistors are described below. For clarity, the following terminology is used in the description herein:
1. CMOS mode and CMOS type—refer to the use of both NMOS and PMOS transistors as gain transistors in a multi-mode oscillator,
2. NMOS mode and NMOS type—refer to the use of only NMOS transistors as gain transistors in a multi-mode oscillator,
3. PMOS-mode and PMOS-type—refer to the use of only PMOS transistors as gain transistors in a multi-mode oscillator,
4. Complementary mode—refer to the use of two complementary types of transistors (e.g., both NMOS transistors and PMOS transistors) as gain transistors in a multi-mode oscillator, and
5. Non-complementary-mode—refers the use of a single type of transistors (e.g., only NMOS transistors or only PMOS transistors) as gain transistors in a multi-mode oscillator.

A multi-mode oscillator may support an NMOS mode with a first oscillator topology and a CMOS mode with a second oscillator topology. The multi-mode oscillator can thus change its topology according to different oscillator requirements of multiple radio technologies, e.g., GSM and WCDMA. The NMOS mode may use only NMOS transistors as gain transistors, may have good phase noise performance, may be selected for GSM and/or other radio technologies having more stringent phase noise requirements, and may be able to operate with a lower power supply voltage. The CMOS mode may use both NMOS transistors and PMOS transistors as gain transistors, may have lower power consumption, and may be selected for WCDMA and/or other radio technologies having less stringent phase noise requirements. The NMOS mode may also be referred to as a high performance mode, a non-complementary mode, etc. The CMOS mode may also be referred to as a low power mode, a complementary mode, etc.

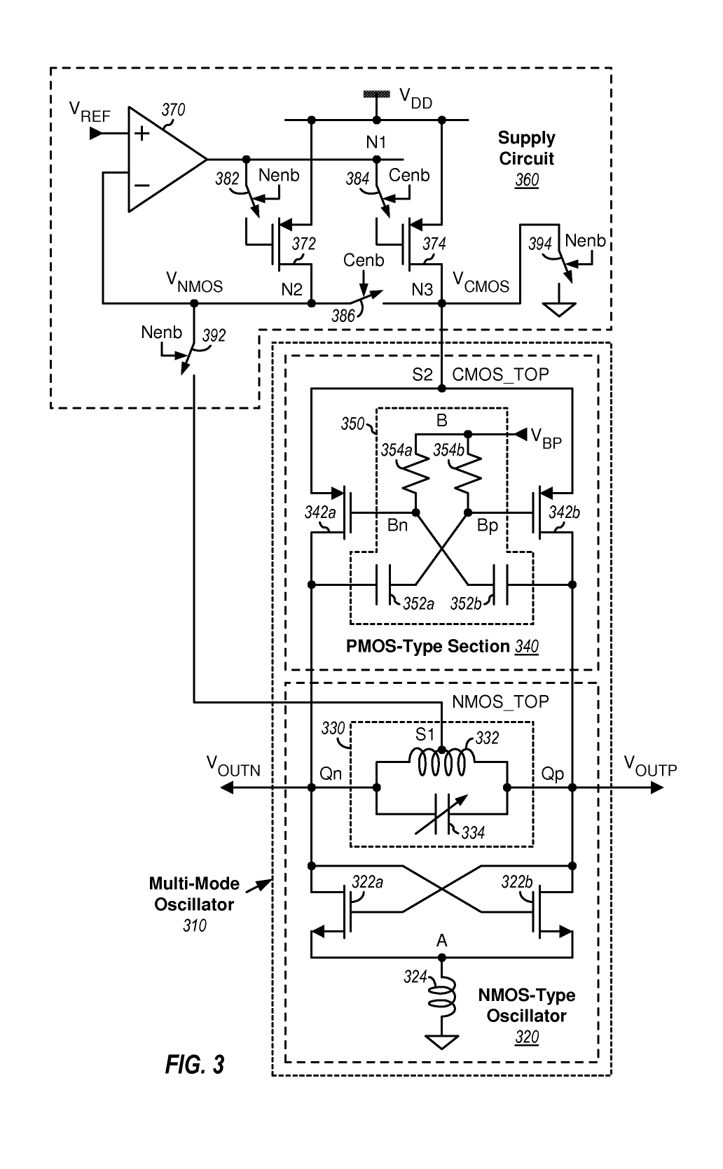

FIG. 3 shows a schematic diagram of an exemplary design of a multi-mode oscillator 310 supporting an NMOS mode and a CMOS mode. Multi-mode oscillator 310 may be used for each of VCOs 214, 274 and 284 in FIG. 2. Multi-mode oscillator 310 includes an NMOS-type oscillator 320 and a PMOS-type section 340.

NMOS-type oscillator 320 includes NMOS transistors 322a and 322b cross-coupled together and acting as gain transistors for multi-mode oscillator 310 in the NMOS mode and the CMOS mode. NMOS transistor 322a has its source coupled to node A, its gate coupled to node Qp, and its drain coupled to node Qn. NMOS transistor 322b has its source coupled to node A, its gate coupled to node Qn, and its drain coupled to node Qp. An inductor 324 is coupled between node A and circuit ground. A tank circuit 330 is coupled between node Qp and node Qn. In the exemplary design shown in FIG. 3, tank circuit 330 includes an inductor 332 coupled in parallel with an adjustable capacitor 334, with the parallel combination being coupled between node Qp and node Qn. Inductor 332 has a center tap coupled to a first supply node S1. Node S1 is also referred to as an NMOS_TOP node, which is the node that is applied with a supply voltage for the oscillator in the NMOS mode. Adjustable capacitor 334 may comprise one or more variable capacitors (varactors). Each varactor has a capacitance that can be varied based on an analog control voltage. Alternatively or additionally, adjustable capacitor 334 may comprise a bank of switchable capacitors. Each switchable capacitor may be selected to increase the capacitance of tank circuit 330 or unselected to reduce the capacitance of tank circuit 330. Adjustable capacitor 334 may also include other types of capacitors, e.g., one or more fixed capacitors, with each fixed capacitor having a fixed capacitance value.

PMOS-type section 340 includes PMOS transistors 342a and 342b cross-coupled together and acting as gain transistors for multi-mode oscillator 310 in the CMOS mode. PMOS transistor 342a has its source coupled to a second supply node S2, its gate coupled to node Bn, and its drain coupled to node Qn. PMOS transistor 342b has its source coupled to node S2, its gate coupled to node Bp, and its drain coupled to node Qp. Node S2 is also referred to as a CMOS_TOP node, which is the node that is applied with a supply voltage for the oscillator in the CMOS mode. PMOS-type section 340 further includes a cross-coupled RC circuit 350 to provide biasing for PMOS transistors 342a and 342b. RC circuit 350 includes capacitors 352a and 352b and resistors 354a and 354b. Capacitor 352a is coupled between node Qn and node Bp, and capacitor 352b is coupled between node Qp and node Bn. Resistor 354a is coupled between node Bn and node B, and resistor 354b is coupled between node Bp and node B. A bias voltage V_{BP} is applied to node B.

FIG. 3 shows a specific design of NMOS-type oscillator 320 and PMOS-type section 340. NMOS-type oscillator 320 may also be implemented in other manners. For example, inductor 324 may be omitted, and the sources of NMOS transistors 322a and 322b may be coupled directly to circuit ground. As another example, inductor 324 may be replaced by an NMOS transistor having its gate biased by a current minor, its drain coupled to node A, and its source coupled to circuit ground. This NMOS transistor may provide a bias current for the multi-mode oscillator in either the NMOS mode or the CMOS mode. PMOS-type section 340 may also be implemented in other manners. For example, capacitors 352a and 352b and resistors 354a and 354b may be omitted, and PMOS transistors 342a and 342b may be cross-coupled in similar manner as NMOS transistors 322a and 322b. As another example, PMOS transistors 342a and 342b may be cross coupled through a transformer.

FIG. 3 also shows a schematic diagram of an exemplary design of a supply circuit 360 that provides supply voltages for multi-mode oscillator 310. Within supply circuit 360, an operational amplifier (op-amp) 370 has its non-inverting input receiving a reference voltage V_{REF}, its inverting input coupled to node N2, and its output providing a control voltage on node N1. A PMOS transistor 372 has its source coupled to a power supply voltage V_{DD}, its gate coupled to node N1 via a switch 382, and its drain coupled to node N2. A PMOS transistor 374 has its source coupled to the V_{DD} power supply voltage, its gate coupled to node N1 via a switch 384, and its drain coupled to node N3. PMOS transistors 372 and 374 are not gain transistors for multi-mode oscillator 310. A switch 386 is coupled between node N2 and node N3. A switch 392 is coupled between node N2 within supply circuit 360 and the first supply node S1 within NMOS-type oscillator 320. A switch 394 is coupled between node N3 and circuit ground. Node N3 corresponds to the second supply node S2 within PMOS-type section 340. Switches 382, 392 and 394 are controlled by an NMOS enable (Nenb) signal. Switches 384 and 386 are controlled by a CMOS enable (Cenb) signal.

FIG. 3 shows a specific design of supply circuit 360. Supply circuit 360 may also be implemented in other manners. For example, op-amp 370 may be omitted, PMOS transistor 372 may operate as a switch and may have its drain coupled directly to the NMOS_TOP node. PMOS transistor 372 may be (i) turned on to provide the V_{NMOS} supply voltage to the NMOS_TOP node or (ii) turned off to float the NMOS_TOP node. Similarly, PMOS transistor 376 may operate as a switch and may be (i) turned on to provide the V_{CMOS} supply voltage to the CMOS_TOP node or (ii) turned off to remove the V_{CMOS} supply voltage from the CMOS_TOP node. As another example, two op-amps may be used instead of one op-amp 370. A first op-amp may control PMOS transistor 372 to provide the V_{NMOS} supply voltage in the NMOS mode. A second op-amp may control PMOS transistor 374 to provide the V_{CMOS} supply voltage in the CMOS mode. A current minor may also be used to provide a bias current to the NMOS_TOP node. The current minor may comprise PMOS transistor 372 and an additional PMOS transistor. Switch 392 may be coupled to the drain of the additional PMOS transistor instead of the drain of PMOS transistor 372.

FIG. 3 shows an exemplary design of supply circuit 360 with a single power supply voltage. Multiple power supply voltages may also be supported. For example, an additional PMOS transistor may be coupled in the same manner as PMOS transistor 374, except with the source of the additional PMOS transistor being coupled to a second power supply voltage V_{DD2}. PMOS transistor 374 may be enabled to use the V_{DD} power supply voltage, or the additional PMOS transistor may be enabled to use the V_{DD2} power supply voltage. Multiple different power supply voltages may be used to obtain different characteristics such as better phase noise characteristics, lower power consumption, etc.

Multi-mode oscillator 310 may operate in the NMOS mode or the CMOS mode at any given moment. The NMOS mode may be selected to obtain good phase noise performance (even with a limited supply voltage), which may be desirable for GSM and other radio technologies having more stringent phase noise requirements. The CMOS mode may be selected to obtain low power consumption, which may be desirable for WCDMA and other radio technologies having less stringent phase noise requirements. The NMOS mode or the CMOS mode may also be selected based on other criteria besides radio technology. For example, the NMOS mode may be selected for higher modulation order (e.g., 16 QAM or higher), and the CMOS mode may be selected for lower modulation order (e.g., BPSK or QPSK). As another example, the NMOS mode may be selected for high received signal quality, and the CMOS mode may be selected for low received signal quality.

In the NMOS mode, the Nenb signal is activated to generate the V_{NMOS} supply voltage for NMOS-type oscillator 320, and the Cenb signal is deactivated to disable PMOS-type section 340. In the CMOS mode, the Nenb signal is deactivated, and the Cenb signal is activated to generate the V_{CMOS} supply voltage for both NMOS-type oscillator 320 and PMOS-type section 340.

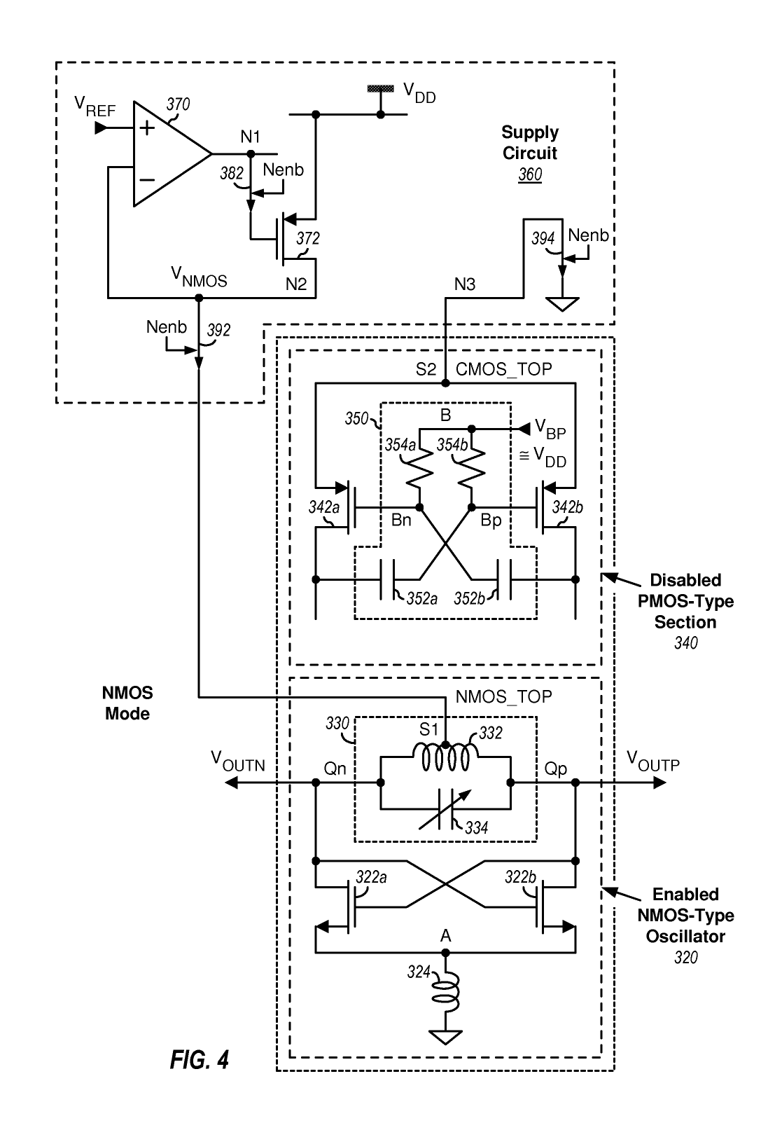

FIG. 4 shows a schematic diagram of multi-mode oscillator 310 and supply circuit 360 in the NMOS node. For clarity, only the portion of supply circuit 360 that is pertinent in the NMOS mode is shown in FIG. 4. In the NMOS mode, NMOS-type oscillator 320 is enabled, and PMOS-type section 340 is disabled. Supply circuit 360 provides the V_{NMOS} supply voltage for NMOS-type oscillator 320 via switch 392 to the NMOS_TOP node. Supply circuit 360 also removes the V_{CMOS} supply voltage for PMOS-type section 340 and shorts the CMOS_TOP node to circuit ground via switch 394.

In the NMOS mode, the Nenb signal is activated, switches 382, 392 and 394 within supply circuit 360 are closed. PMOS transistor 372 is connected in a feedback loop with op-amp 370, which generates a control voltage at node N1 such that the V_{NMOS} supply voltage is equal to the V_{REF} voltage. The V_{NMOS} supply voltage is provided to the NMOS_TOP node of NMOS-type oscillator 320 via switch 392. NMOS-type oscillator 320 is turned on by the V_{NMOS} supply voltage.

In the NMOS mode, the Cenb signal is deactivated, switches 384 and 386 within supply circuit 360 are opened (not shown in FIG. 3), and switch 394 is closed. The CMOS_TOP node of PMOS-type section 340 is shorted to circuit ground via switch 394. The V_{BP} bias voltage for PMOS transistors 342a and 342b is set to a high voltage (e.g., V_{BP}≈V_{DD}) to turn off PMOS transistors 342a and 342b and disable PMOS-type section 340. Cross-coupled RC circuit 350 functions as a switch to turn off PMOS transistors 342a and 342b in the NMOS mode.

NMOS-type oscillator 320 operates as follows in the NMOS mode. The V_{NMOS} supply voltage is provided to the centertap of inductor 332 at the NMOS_TOP node by supply circuit 360. NMOS transistors 322a and 322b are gain transistors that provide signal gain for the oscillator. Inductor 324 provides bias current for NMOS transistors 322a and 322b. Inductor 324 also improves phase noise performance of the oscillator when a proper inductance value is selected. The inductance and capacitance of tank circuit 330 determine the frequency of oscillation of NMOS-type oscillator 320. Adjustable capacitor 334 may be varied to adjust the oscillator frequency to a target frequency.

As shown in FIG. 4, in the NMOS mode, the oscillator supply voltage is applied to the NMOS_TOP node, and the CMOS_TOP node is grounded. The V_{BP} voltage may be set to the power supply voltage (e.g., V_{DD}) to turn off PMOS transistors 342a and 342b. NMOS-type oscillator 320 is active in the NMOS mode and has lower phase noise for a given headroom of the oscillator supply voltage.

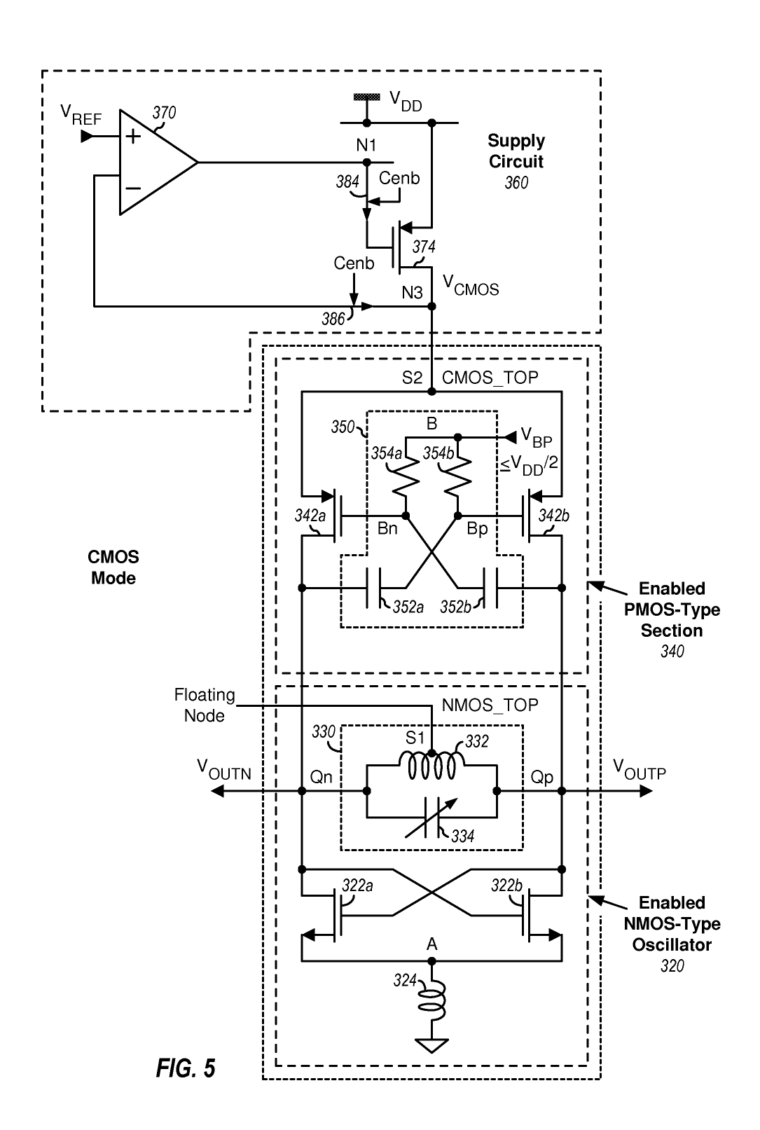

FIG. 5 shows a schematic diagram of multi-mode oscillator 310 and supply circuit 360 in the CMOS node. For clarity, only the portion of supply circuit 360 that is pertinent in the CMOS mode is shown in FIG. 5. In the CMOS mode, both NMOS-type oscillator 320 and PMOS-type section 340 are enabled. Supply circuit 360 provides the V_{CMOS} supply voltage for both NMOS-type oscillator 320 and PMOS-type section 340 to the CMOS_TOP node. Supply circuit 360 removes the V_{NMOS} supply voltage from the NMOS_TOP node, which floats as shown in FIG. 5.

In the CMOS mode, the Nenb signal is deactivated, switches 382, 392 and 394 within supply circuit 360 are opened (not shown in FIG. 5). The Cenb signal is activated, and switches 384 and 386 within supply circuit 360 are closed. PMOS transistor 374 is connected in a feedback loop with op-amp 370, which generates a control voltage at node N1 such that the V_{CMOS} supply voltage at node N3 is equal to the V_{REF} voltage. PMOS transistor 374 provides the V_{CMOS} supply voltage to the CMOS_TOP node.

In the CMOS mode, the V_{BP} bias voltage is set to a low voltage (e.g., V_{BP}≦V_{DD}/2) to turn on PMOS transistors 342a and 342b and enabled PMOS-type section 340. Setting the V_{BP} bias voltage to less than V_{DD}/2 may extend the headroom of multi-mode oscillator 310, which may enable multi-mode oscillator 310 to operate with a lower power supply voltage. For example, the V_{BP} bias voltage may be (i) set to approximately 0.5 to 0.6 Volts (V) when the V_{DD} power supply voltage is 1.3V or (ii) set to approximately 0.8V to 0.9V when the V_{DD} power supply voltage is 2.1V.

NMOS-type oscillator 320 and PMOS-type section 340 operate as follows in the CMOS mode. The V_{CMOS} supply voltage is provided to the CMOS_TOP node and powers on both NMOS-type oscillator 320 and PMOS-type section 340. NMOS transistors 322a and 322b as well as PMOS transistors 342a and 342b are gain transistors that provide signal gain for the oscillator. The inductance and capacitance of tank circuit 330 determine the frequency of oscillation of NMOS-type oscillator 320 and PMOS-type section 340 in the CMOS mode.

As shown in FIG. 5, in the CMOS mode, the oscillator supply voltage is applied to the CMOS_TOP node, and the NMOS_TOP node floats. Cross-coupled RC circuit 350 functions as a DC bias circuit. The V_{BP} bias voltage may be set to one half of the power supply voltage or less (e.g., V_{BP}≦V_{DD}/2) to turn on PMOS transistors 342a and 342b. This V_{BP} bias voltage lowers the gate DC voltage of PMOS transistors 342a and 342b. Hence, multi-mode oscillator 310 in the CMOS mode can alleviate a power supply headroom issue and operate at a lower power supply voltage than a conventional CMOS oscillator. For example, multi-mode oscillator 310 may be able to operate with a 1.3V power supply voltage in the CMOS mode. Multi-mode oscillator 310 may consume less current with the lower power supply voltage while operating as a CMOS-type oscillator in the CMOS mode than a counterpart NMOS-type oscillator.

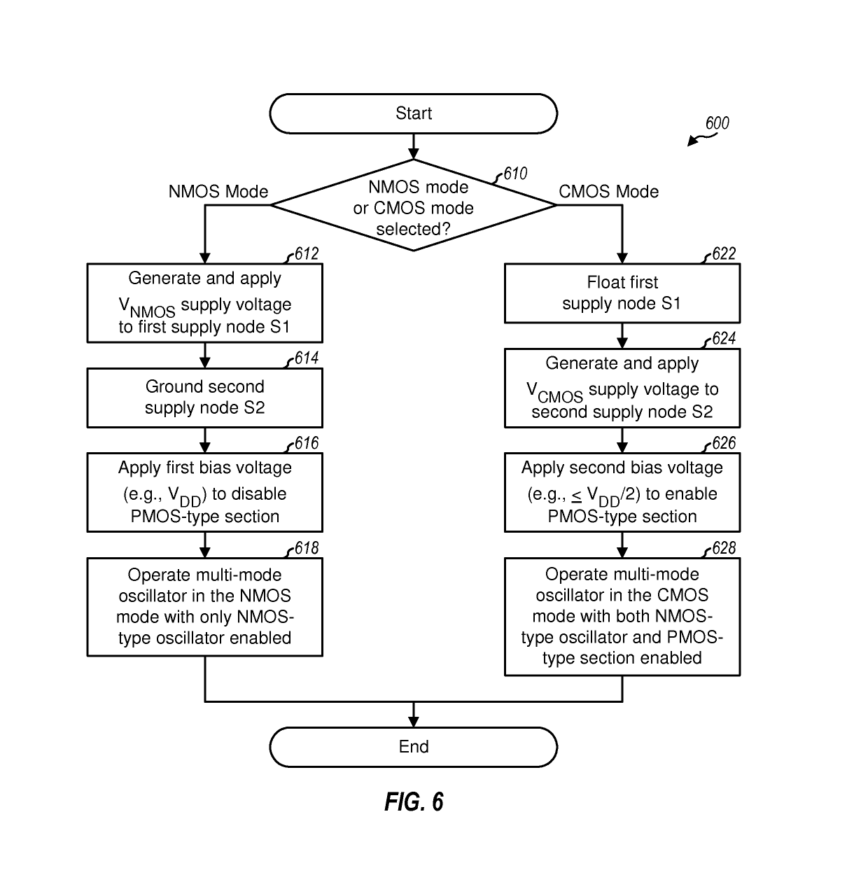

FIG. 6 shows an exemplary design of a process 600 for operating multi-mode oscillator 310 in FIG. 3. A determination may be made whether the NMOS mode or the CMOS mode is selected for multi-mode oscillator 310 (block 610). If the NMOS mode is selected, then the V_{NMOS} supply voltage may be generated and applied to the first supply node S1 of multi-mode oscillator 310 to enable NMOS-type oscillator 320 (block 612). The second supply node S2 of multi-mode oscillator 310 may be grounded to disable PMOS-type section 340 (block 614). A first bias voltage (e.g., V_{BP}≈V_{DD}) may be applied to PMOS transistors 342 within PMOS-type section 340 to disable the PMOS transistors (block 616). Multi-mode oscillator 310 may then be operated in the NMOS mode with only NMOS-type oscillator 320 being enabled (block 618).

Alternatively, if the CMOS mode is selected, as determined in block 610, then the first supply node S1 of multi-mode oscillator 310 may be floated (block 622). The V_{CMOS} supply voltage may be generated and applied to the second supply node S2 of multi-mode oscillator 310 to enable both NMOS-type oscillator 320 and PMOS-type section 340 (block 624). A second bias voltage (e.g., V_{BP}≦V_{DD}/2) may be applied to PMOS transistors 342 within PMOS-type section 340 to enable the PMOS transistors (block 626). Multi-mode oscillator 310 may then be operated in the CMOS mode with both NMOS-type oscillator 320 and PMOS-type section 340 being enabled (block 628).

As shown in FIGS. 3 to 6, multi-mode oscillator 310 has various distinctive characteristics. First, multi-mode oscillator 310 can operate in (i) the NMOS mode in which only NMOS-type oscillator 320 is enabled or (ii) the CMOS mode in which both NMOS-type oscillator 320 and PMOS-type section 340 are enabled. The V_{BP} bias voltage may be set to a high voltage (e.g., V_{DD}) to disable PMOS-type section 340 or to a lower voltage (e.g., ≦V_{DD}/2) to enable PMOS-type section 340. Multi-mode oscillator 310 can operate as an NMOS-type oscillator when PMOS-type section 340 is disabled and as a CMOS-type oscillator when PMOS-type section 340 is enabled. Second, multi-mode oscillator 310 receives its supply voltage at different nodes depending on whether it is operating in the NMOS mode or the CMOS mode. In particular, the V_{NMOS} supply voltage is applied to the NMOS_TOP node in the NMOS mode, and the V_{CMOS} supply voltage is applied to the CMOS_TOP node in the CMOS mode. Third, switches are not used to connect/disconnect the drains of PMOS transistors 342a and 342b to/from the drains of NMOS transistors 322a and 322b, respectively. These switches would increase the power supply voltage needed for proper operation. Omitting these switches allows multi-mode oscillator 310 to operate with a lower power supply voltage (e.g., 1.3V) in the CMOS mode. Fourth, cross-coupled RC circuit 350 enables a lower bias voltage to be applied to the gates of PMOS transistors 342a and 342b, which enables multi-mode oscillator 310 to operate with a lower power supply voltage in the CMOS mode. Greater power savings may be achieved with multi-mode oscillator 310 operating with a lower power supply voltage in the CMOS mode.

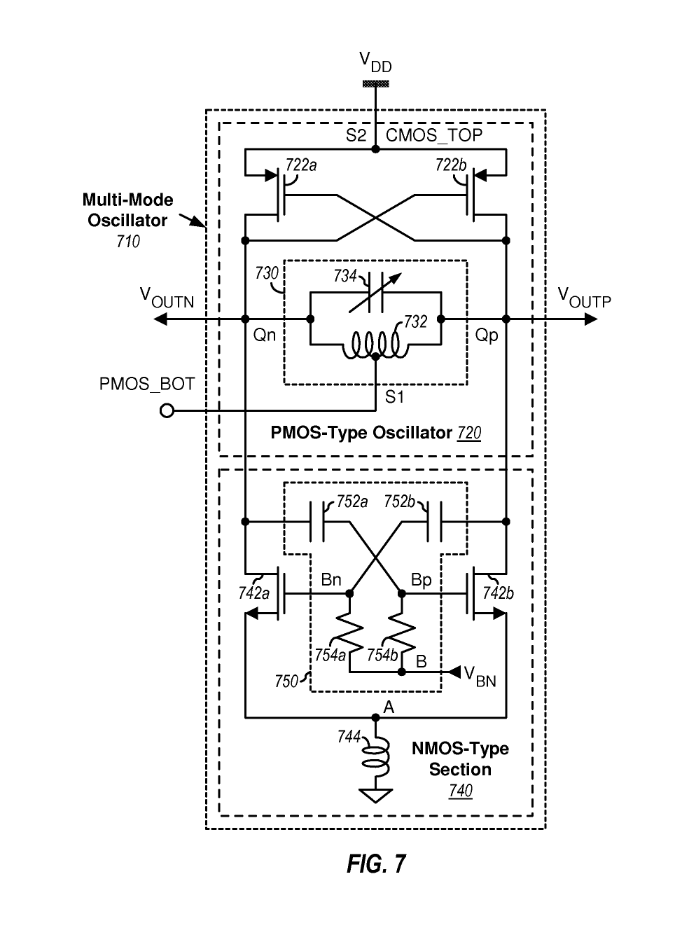

FIG. 7 shows a schematic diagram of an exemplary design of a multi-mode oscillator 710 supporting a PMOS mode and a CMOS mode. Multi-mode oscillator 710 may be used for each of VCOs 214, 274 and 284 in FIG. 2. Multi-mode oscillator 710 includes a PMOS-type oscillator 720 and an NMOS-type section 740.

PMOS-type oscillator 720 includes PMOS transistors 722a and 722b cross-coupled together and acting as gain transistors for multi-mode oscillator 710 in the PMOS mode and the CMOS mode. PMOS transistor 722a has its source coupled to a supply node S2, its gate coupled to node Qp, and its drain coupled to node Qn. PMOS transistor 722b has its source coupled to node S2, its gate coupled to node Qn, and its drain coupled to node Qp. Node S2 is also referred to as a CMOS_TOP node, which is the node that is applied with a supply voltage for the oscillator in the CMOS mode. A tank circuit 730 is coupled between node Qp and node Qn. In the exemplary design shown in FIG. 7, tank circuit 730 includes an inductor 732 coupled in parallel with an adjustable capacitor 734, with the parallel combination being coupled between node Qp and node Qn. Inductor 732 has a center tap coupled to a supply node S1. Node S1 is also referred to as a PMOS_BOT node, which is the node that is applied with a lower supply voltage for the oscillator in the PMOS mode.

NMOS-type section 740 includes NMOS transistors 742a and 742b cross-coupled together and acting as gain transistors for multi-mode oscillator 710 in the CMOS mode. NMOS transistor 742a has its source coupled to node A, its gate coupled to node Bn, and its drain coupled to node Qn. NMOS transistor 742b has its source coupled to node A, its gate coupled to node Bp, and its drain coupled to node Qp. An inductor 744 is coupled between node A and circuit ground. NMOS-type section 740 further includes a cross-coupled RC circuit 750 to provide biasing for NMOS transistors 742a and 742b. RC circuit 750 includes capacitors 752a and 752b and resistors 754a and 754b. Capacitor 752a is coupled between node Qn and node Bp, and capacitor 752b is coupled between node Qp and node Bn. Resistor 754a is coupled between node Bn and node B, and resistor 754b is coupled between node Bp and node B. A bias voltage V_{BN} is applied to node B.

FIG. 7 shows a specific design of PMOS-type oscillator 720 and NMOS-type section 740. PMOS-type oscillator 720 and NMOS-type section 740 may also be implemented in other manners.

Multi-mode oscillator 710 may operate in the PMOS mode or the CMOS mode at any given moment. In both the PMOS mode and the CMOS mode, a V_{DD} power supply voltage is applied to the CMOS_TOP node. In the PMOS mode, a V_{PMOS} supply voltage (e.g., 0V) is applied to the PMOS_BOT node of PMOS-type oscillator 720, and the V_{BN} bias voltage is set to a low voltage (e.g., 0V) to disable NMOS-type section 740. In the CMOS mode, the PMOS_BOT node floats, and the V_{BN} bias voltage is set to a suitable voltage (e.g., V_{BN}≧V_{DD}/2) to enable NMOS-type section 740.

The multi-mode oscillators described herein may provide various advantages. The multi-mode oscillators may enable a wireless device to support multiple radio technologies (e.g., GSM and WCDMA) having different oscillator requirements (e.g., with one silicon chipset). The multi-mode oscillators can change their topologies according to different oscillator requirements of different radio technologies.

In an exemplary design, an apparatus (e.g., a wireless device, an IC, a circuit module, etc.) may include first and second transistors of a first transistor type and third and fourth transistors of a second transistor type for a multi-mode oscillator. The second transistor type may be complementary to the first transistor type, e.g., P-type versus N-type. The third and fourth transistors may be coupled to the first and second transistors. In one design, the third and fourth transistors may have their drains coupled directly to the drains of the first and second transistors, respectively, as shown in FIG. 3. The first and second transistors may be enabled in a first mode to provide signal gain for the oscillator and generate an oscillator signal in the first mode. The first, second, third and fourth transistors may be enabled in a second mode to provide signal gain for the oscillator and generate the oscillator signal in the second mode. The third and fourth transistors may be disabled in the first mode.

The multi-mode oscillator may comprise a first oscillator circuit and a second oscillator circuit. The first oscillator circuit (e.g., NMOS-type oscillator 320 in FIG. 3) may comprise the first and second transistors of the first transistor type and may be enabled in the first mode to generate the oscillator signal. The second oscillator circuit (e.g., PMOS-type section 340 in FIG. 3) may comprise the third and fourth transistors of the second transistor type. The first and second oscillator circuits may both be enabled in the second mode to generate the oscillator signal.

In one design, the first and second transistors may comprise NMOS transistors (e.g., NMOS transistors 322a and 322b in FIG. 3), and the third and fourth transistors may comprise PMOS transistors (e.g., PMOS transistors 342a and 342b in FIG. 3). The first mode may correspond to the NMOS mode with only the NMOS transistors being enabled. The second mode may correspond to the CMOS mode with both the NMOS transistors and the PMOS transistors being enabled.

In another design, the first and second transistors may comprise PMOS transistors (e.g., PMOS transistors 722a and 722b in FIG. 7), and the third and fourth transistors may comprise NMOS transistors (e.g., NMOS transistors 742a and 742b in FIG. 7). The first mode may correspond to the PMOS mode with only the PMOS transistors being enabled. The second mode may correspond to the CMOS mode with both the NMOS transistors and the PMOS transistors being enabled. The first through fourth transistors may also comprise transistors of other types.

In one design, the apparatus may further include a cross-coupled RC circuit (e.g., RC circuit 350 in FIG. 3) coupled between the third and fourth transistors. The cross-coupled RC circuit may function as a switch to disable the third and fourth transistors in the first mode. The cross-coupled RC circuit may also enable a suitable bias voltage to be applied to the third and fourth transistors in the second mode to provide more headroom and enable a lower power supply voltage to be used in the second mode.

In one design, the cross-coupled RC circuit may include first and second capacitors and first and second resistors. The first capacitor (e.g., capacitor 352a) may be coupled between the gate of the third transistor (e.g., PMOS transistor 342a) and the drain of the fourth transistor (e.g., PMOS transistor 342b). The second capacitor (e.g., capacitor 352b) may be coupled between the gate of the fourth transistor and the drain of the third transistor. The first resistor (e.g., resistor 354a) may be coupled between the gate of the third transistor and a bias node. The second resistor (e.g., resistor 354b) may be coupled between the gate of the fourth transistor and the bias node. The bias node may receive a bias voltage for the third and fourth transistors.

In one design, the apparatus may further include a tank circuit (e.g., tank circuit 330 in FIG. 3) comprising an inductor and an adjustable capacitor coupled in parallel. The inductor may have a centertap configured to receive a first supply voltage for the first and second transistors in the first mode.

In one design, the apparatus may further include a supply circuit (e.g., supply circuit 360 in FIG. 3) to generate a suitable supply voltage for the multi-mode oscillator in each mode. The supply circuit may provide the first supply voltage (e.g., the V_{NMOS} supply voltage) at a first supply node S1 for the first and second transistors in the first mode. The supply circuit may float the first supply node in the second mode. The supply circuit may provide a second supply voltage (e.g., the V_{CMOS} supply voltage) at a second supply node S2 for the first, second, third, and fourth transistors in the second mode. The supply circuit may couple the second supply node to circuit ground in the first mode to disable the third and fourth transistors in the first mode. The second supply voltage for the second mode may be equal to the first supply voltage for the first mode. Alternatively, the second supply voltage for the second mode may be different from (e.g., larger than) the first supply voltage for the first mode.

In one design, the supply circuit may include an op-amp and fifth and sixth transistors. In the first mode, the op-amp (e.g., op-amp 370 in FIG. 3) may receive a reference voltage at a non-inverting input and the first supply voltage at an inverting input and may provide a control voltage to maintain the first supply voltage equal to the reference voltage. The fifth transistor (e.g., PMOS transistor 372 in FIG. 3) may have a gate coupled to the output of the op-amp, a source coupled to a power supply voltage (e.g., V_{DD}), and a drain providing the first supply voltage. In the second mode, the op-amp may receive the second supply voltage at the inverting input and may provide the control voltage to maintain the second supply voltage equal to the reference voltage in the second mode. The sixth transistor (e.g., PMOS transistor 374) may have a gate coupled to the output of the op-amp, a source coupled to the power supply voltage, and a drain providing the second supply voltage at the second supply node. The supply circuit may also be implemented in other manners.

In one design, the first and second transistors (e.g., NMOS transistors 322a and 322b in FIG. 3) may be cross-coupled and self-biased. In one design, the third and fourth transistors (e.g., PMOS transistors 342a and 342b in FIG. 3) may receive (i) a first bias voltage to disable the third and four transistors in the first mode or (ii) a second bias voltage to enable the third and four transistors in the second mode. The first bias voltage may be set to a supply voltage, and the second bias voltage may be set to one half of the supply voltage or less. The first and second bias voltages may also be set to other voltages.

In one design, the first mode may be selected for a first radio technology, and the second mode may be selected for a second radio technology. The first radio technology may correspond to GSM, LTE, etc. The second radio technology may correspond to WCDMA, CDMA lx, etc. The first or second mode may also be selected based on other criteria such as modulation order, received signal quality, etc.

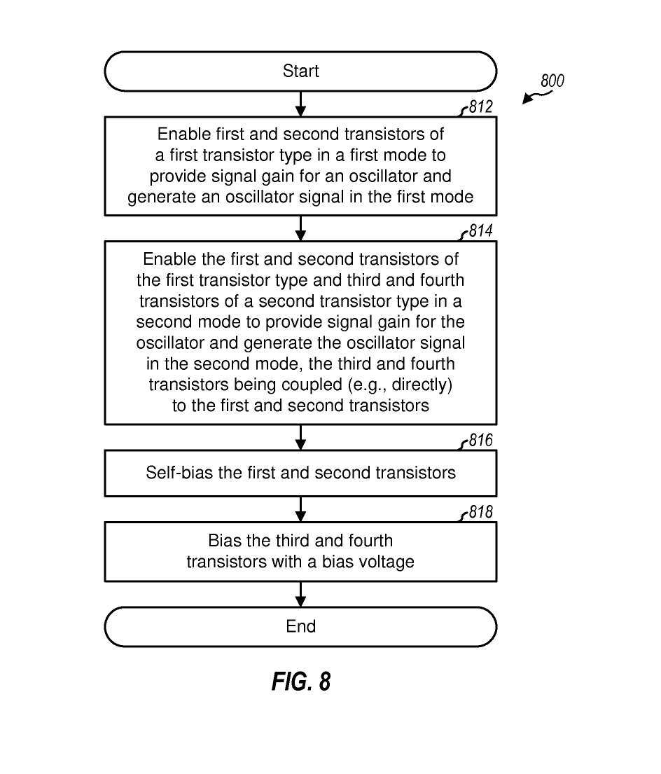

FIG. 8 shows an exemplary design of a process 800 for generating an oscillator signal. First and second transistors of a first transistor type may be enabled in a first mode to provide signal gain for an oscillator and generate an oscillator signal in the first mode (block 812). The first and second transistors of the first transistor type as well as third and fourth transistors of a second transistor type may be enabled in a second mode to provide signal gain for the oscillator and generate the oscillator signal in the second mode (block 814). The third and fourth transistors may be coupled (e.g., directly) to the first and second transistors and may be disabled in the first mode.

In one design of block 812, a first supply voltage may be provided at a first supply node for the first and second transistors in the first mode. The first supply node may be floated in the second mode. In one design of block 814, a second supply voltage may be provided at a second supply node for the first, second, third, and fourth transistors in the second mode. The second supply node may be coupled to circuit ground in the first mode to disable the third and fourth transistors in the first mode.

In one design, the first and second transistors may be self-biased (block 816). The third and fourth transistors may be biased with a bias voltage (block 818). In one design of block 818, a first bias voltage may be provided to disable the third and fourth transistors in the first mode. A second bias voltage may be provided to enable the third and fourth transistors in the second mode.

In one design, the first mode may be selected for a first radio technology, and the second mode may be selected for a second radio technology. The first or second mode may also be selected based on other criteria such as modulation order, received signal quality, etc.

Those of skill in the art would understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the disclosure herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein but is to be accorded the widest scope consistent with the principles and novel features disclosed herein.

What is claimed is:

1. An apparatus comprising:
first and second transistors of a first transistor type for an oscillator, the first and second transistors being enabled in a first mode to provide signal gain for the oscillator and generate an oscillator signal in the first mode; and
third and fourth transistors of a second transistor type coupled to the first and second transistors of the first transistor type, the first, second, third and fourth transistors being enabled in a second mode to provide signal gain for the oscillator and generate the oscillator signal in the second mode.

2. The apparatus of claim 1, the first and second transistors comprising N-channel metal oxide semiconductor (NMOS) transistors, the third and fourth transistors comprising P-channel metal oxide semiconductor (PMOS) transistors, the first mode corresponding to an NMOS mode with only the NMOS transistors being enabled, and the second mode corresponding to a complementary metal oxide semiconductor (CMOS) mode with both the NMOS transistors and the PMOS transistors being enabled.

3. The apparatus of claim 1, the first and second transistors comprising P-channel metal oxide semiconductor (PMOS) transistors, the third and fourth transistors comprising N-channel metal oxide semiconductor (NMOS) transistors, the first mode corresponding to a PMOS mode with only the PMOS transistors being enabled, and the second mode corresponding to a complementary metal oxide semiconductor (CMOS) mode with both the NMOS transistors and the PMOS transistors being enabled.

4. The apparatus of claim 1, further comprising:
a cross-coupled resistor-capacitor (RC) circuit coupled between the third and fourth transistors.

5. The apparatus of claim 4, the cross-coupled RC circuit comprising
a first capacitor coupled between a gate of the third transistor and a drain of the fourth transistor,
a second capacitor coupled between a gate of the fourth transistor and a drain of the third transistor,
a first resistor coupled between the gate of the third transistor and a bias node, and
a second resistor coupled between the gate of the fourth transistor and the bias node, the bias node receiving a bias voltage for the third and fourth transistors.

6. The apparatus of claim 1, further comprising:
a tank circuit comprising an inductor and an adjustable capacitor coupled in parallel.

7. The apparatus of claim 6, the inductor having a centertap configured to receive a first supply voltage for the first and second transistors in the first mode.

8. The apparatus of claim 1, further comprising:
a supply circuit configured to provide a first supply voltage at a first supply node for the first and second transistors in the first mode.

9. The apparatus of claim 8, the supply circuit is further configured to float the first supply node in the second mode.

10. The apparatus of claim 8, the supply circuit is further configured to provide a second supply voltage at a second supply node for the first, second, third, and fourth transistors in the second mode.

11. The apparatus of claim 10, the supply circuit is further configured to couple the second supply node to circuit ground in the first mode to disable the third and fourth transistors in the first mode.

12. The apparatus of claim 8, the supply circuit comprising:
an operational amplifier (op-amp) configured to receive a reference voltage at a non-inverting input and the first supply voltage at an inverting input in the first mode and to provide a control voltage to maintain the first supply voltage equal to the reference voltage in the first mode, and
a fifth transistor having a gate coupled to an output of the op-amp in the first mode, a source coupled to a power supply voltage, and a drain providing the first supply voltage in the first mode.

13. The apparatus of claim 12, the supply circuit further comprising:
a sixth transistor having a gate coupled to the output of the op-amp in the second mode, a source coupled to the power supply voltage, and a drain providing a second supply voltage at a second supply node for the first, second, third, and fourth transistors in the second mode,
wherein the op-amp is further configured to receive the second supply voltage at the inverting input in the second mode and to provide the control voltage to maintain the second supply voltage equal to the reference voltage in the second mode.

14. The apparatus of claim 1, the third and fourth transistors are configured to receive a first bias voltage to disable the third and four transistors in the first mode or a second bias voltage to enable the third and four transistors in the second mode.

15. The apparatus of claim 14, the first bias voltage being set to a supply voltage, and the second bias voltage being set to one half of the supply voltage or less.

16. The apparatus of claim 1, the first and second transistors being cross-coupled and self-biased.

17. The apparatus of claim 1, the first mode being selected for a first radio technology, and the second mode being selected for a second radio technology.

18. The apparatus of claim 17, the first radio technology corresponding to Global System for Mobile Communications (GSM) or Long Term Evolution (LTE), and the second radio technology corresponding to Wideband Code Division Multiple Access (WCDMA) or CDMA 1X.

19. A method of generating an oscillator signal, comprising:
enabling first and second transistors of a first transistor type in a first mode to provide signal gain for an oscillator and generate an oscillator signal in the first mode; and
enabling the first and second transistors of the first transistor type and third and fourth transistors of a second transistor type in a second mode to provide signal gain for the oscillator and generate the oscillator signal in the second mode, the third and fourth transistors being coupled to the first and second transistors.

20. The method of claim 19, further comprising:
providing a first supply voltage at a first supply node to enable the first and second transistors in the first mode.

21. The method of claim 20, further comprising:
providing a second supply voltage at a second supply node to enable the first, second, third, and fourth transistors in the second mode.

22. The method of claim 19, further comprising:
self-biasing the first and second transistors; and
biasing the third and fourth transistors with a bias voltage.

23. The method of claim 19, further comprising:
providing a first bias voltage to disable the third and fourth transistors in the first mode; and
providing a second bias voltage to enable the third and fourth transistors in the second mode.

24. The method of claim 19, further comprising:
selecting the first mode for a first radio technology; and
selecting the second mode for a second radio technology.

25. An apparatus comprising:
means for enabling first and second transistors of a first transistor type in a first mode to provide signal gain for an oscillator and generate an oscillator signal in the first mode; and
means for enabling the first and second transistors of the first transistor type and third and fourth transistors of a second transistor type in a second mode to provide signal gain for the oscillator and generate the oscillator signal in the second mode, the third and fourth transistors being coupled to the first and second transistors.

26. The apparatus of claim 25, further comprising:
means for providing a first supply voltage at a first supply node to enable the first and second transistors in the first mode.

27. The apparatus of claim 26, further comprising:
means for providing a second supply voltage at a second supply node to enable the first, second, third, and fourth transistors in the second mode.

28. The apparatus of claim 25, further comprising:
means for self-biasing the first and second transistors; and
means for biasing the third and fourth transistors with a bias voltage.

29. The apparatus of claim 25, further comprising:
means for providing a first bias voltage to disable the third and fourth transistors in the first mode; and
means for providing a second bias voltage to enable the third and fourth transistors in the second mode.

30. The apparatus of claim 25, further comprising:
means for selecting the first mode for a first radio technology; and
means for selecting the second mode for a second radio technology.

31. A computer program product, comprising:
a non-transitory computer-readable medium comprising:
code for causing at least one processor to enable first and second transistors of a first transistor type in a first mode to provide signal gain for an oscillator and generate an oscillator signal in the first mode; and
code for causing the at least one processor to enable the first and second transistors of the first transistor type and third and fourth transistors of a second transistor type in a second mode to provide signal gain for the oscillator and generate the oscillator signal in the second mode, the third and fourth transistors being coupled to the first and second transistors.
